(19) United States
(12) Patent Application Publication
(10) Pub. No.: US 2023/0112020 A1
(43) Pub. Date: Apr. 13, 2023

(54) PREFORM SOLDER AND BONDING METHOD USING SAME

(71) Applicants: SENJU METAL INDUSTRY CO., LTD., Tokyo (JP); National Institute of Advanced Industrial Science and Technology, Tokyo (JP)

(72) Inventors: Haruya SAKUMA, Tokyo (JP); Kenichi TOMITSUKA, Tokyo (JP); Hisahiko YOSHIDA, Tokyo (JP); Kenji KANAZAWA, Ibaraki (JP); Sei UEMURA, Ibaraki (JP); Takashi NAKAMURA, Miyagi (JP); Masateru NISHIOKA, Miyagi (JP)

(73) Assignees: SENJU METAL INDUSTRY CO., LTD., Tokyo (JP); National Institute of Advanced Industrial Science and Technology, Tokyo (JP)

(21) Appl. No.: 17/779,803

(22) PCT Filed: Nov. 18, 2020
(86) PCT No.: PCT/JP2020/043051

§ 371 Date: May 25, 2022

(30) Foreign Application Priority Data
Nov. 26, 2019 (JP) 2019-213373

(51) Int. Cl. H05K 3/34; B23K 1/00; B23K 35/02; B23K 35/26

(52) U.S. Cl. CPC H05K 3/3478; B23K 1/0008; B23K 35/0238; B23K 35/262; H05K 13/0465

(57) ABSTRACT

A Magnetic-field melting preform solder that melts by action of an AC magnetic field, wherein the preform solder includes a laminated structure made up of two or more layers, at least two layers constituting the laminated structure is made up of solder material, the at least two layers do not contain ferromagnetic material, each of the at least two layers includes a surface facing with each other, and the surfaces facing with each other are in contact with each other. A bonding method using the preform solder includes a providing the preform solder between an electrode on a substrate and an electrode of an electronic component, and bonding together the electrode on the substrate and the electrode of the electronic component by generating an AC magnetic field around the substrate and thereby melting the preform solder.

### FIELD

The present invention relates to preform solder that melts by the action of an AC magnetic field and a bonding method using the preform solder.

### BACKGROUND

PTL 1 discloses a microwave heating device. The heating device generates a microwave as a specific standing wave in a cavity resonator. The heating device keeps the distribution of an electric field and magnetic field in the cavity resonator in a desired state through adjustment of microwave frequency. When the distribution of the electric field and magnetic field is kept in a desired state, a region extremely low in electric field intensity and high in magnetic field intensity is created at the position of the central axis of the cavity resonator. Furthermore, the heating device conveys an object to be heated through this region. The object to be heated is heated by a magnetic field component of the microwave without being affected by the electric field component of the microwave. Note that examples of the object to be heated include an electrode pattern with solder placed thereon.

### CITATION LIST

### Patent Literature

[PTL 1] JP 2019-136771 A

### SUMMARY

### Technical Problem

The technique described in PTL 1 can melt solder by heating the solder directly or indirectly by the action of the magnetic field component. Thus, after repeating active studies by paying attention to the action of the AC magnetic field, the present inventors have found that when AC magnetic field is applied to a laminate of preform solder, temperature rise characteristics different from those obtained when an AC magnetic field is applied to a single-layer body are obtained.

The present invention has been completed based on this finding. An object of the present invention is to provide novel preform solder that can melt by the action of an AC magnetic field and a bonding method using the preform solder.

### Solution to Problem

A first invention is a magnetic-field melting preform solder that melts by action of an AC magnetic field and has the following features.

The preform solder comprising a laminated structure made up of two or more layers.

A second invention further has the following feature in the first invention.

The laminated structure is made up of three or more layers.

A third invention further has the following feature in the first or second invention.

Solder materials forming respective layers of the laminated structure have a same composition.

A fourth invention has the following feature in any one of the first to third inventions.

At least one of the layers making up the laminated structure contains magnetic material.

A fifth invention has the following feature in any one of the first to third inventions.

The laminated structure includes a magnetic layer containing magnetic material.

A sixth invention has the following feature in the fourth or fifth invention.

The magnetic material is ferromagnetic material.

A seventh invention has the following feature in the fourth or fifth invention.

A proportion of the magnetic material to the entire laminated structure is 0.005 to 20% by weight.

An eighth invention is a joining method using the magnetic-field melting solder according to any one of the first to seventh inventions.

The joining method comprising the steps of:
providing the preform solder between an electrode on a substrate and an electrode of an electronic component; and
bonding together the electrode on the substrate and the electrode of the electronic component by generating an AC magnetic field around the substrate and thereby melting the preform solder.

### Advantageous Effects of Invention

The preform solder generates heat by the action of an AC magnetic field. The heat generation is caused at least by eddy-current losses. The closer the eddy current occurring in the preform solder is to a surface of the preform solder, the stronger the eddy current (the skin effect). Therefore, the heat generated by the eddy-current losses moves inward from the surface of the preform solder.

When the preform solder has a single layer, the heat is released outward from the surface of the preform solder. On the other hand, when the preform solder has two or more layers, the movement of heat occurs between the two layers facing each other. Thus, when the preform solder has two or more layers, temperature can be raised in a shorter time than when the preform solder has a single layer.

The present invention is preform solder having a laminated structure made up of two or more layers. Thus, the present invention makes it possible to melt entire solder in a short time.

The bonding method according to the present invention can bond together the electrode on a substrate and the electrode of an electronic component by melting the preform solder according to the present invention using the AC magnetic field generated around the substrate. That is, the present invention makes it possible to melt the preform solder in a short time using an AC magnetic field generated locally and thereby electrically connect the electrodes to each other. This in turn makes it possible to bond together the electrodes while minimizing an impact imposed on the substrate and the electronic component.

### BRIEF DESCRIPTION OF DRAWINGS

FIG. 1 is a schematic diagram showing an example of solder according to an embodiment;

FIG. .2 is a schematic diagram showing another example of solder according to the embodiment;

FIG. .3 is a schematic diagram showing still another example of solder according to the embodiment;

FIG. 4 is a diagram showing an example of a first joining method using the solder according to the embodiment;

FIG. 5 is a diagram showing an example of a second joining method using the solder according to the embodiment;

FIG. 6 is a diagram showing temperature rise history data of the samples prepared in Example 1; and

FIG. 7 is a diagram showing temperature rise history data of the samples prepared in Example 2.

### DESCRIPTION OF EMBODIMETNS

First, solder according to an embodiment of the present invention will be described. Note that when a numerical value range is indicated by “to,” the values at the upper and lower ends are included in the range as the lower and upper limits.

### 1. Preform Solder

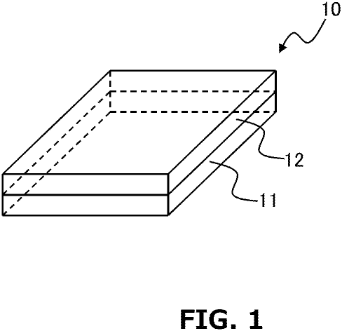

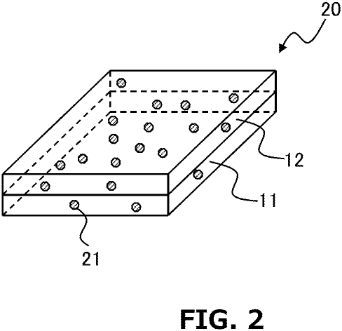

The preform solder is defined as solder formed into a shape such as a ribbon shape, a square shape, a disk shape, a washer shape, a chip shape, or a ring shape. The thickness of the preform solder is 10 to 500 µm. The solder according to the present embodiment is magnetic-field melting preform solder having a laminated structure made up of two or more layers. FIG. 1 is a schematic diagram showing an example of solder according to the present embodiment. The solder 10 shown in FIG. 1 includes a first solder layer 11 and a second solder layer 12. That is, the solder 10 has a two-layer structure.

Both the first solder layer 11 and second solder layer 12 are made of solder material. The solder material is not specifically limited as long as the solder material has the property of generating heat due to at least eddy-current losses when placed in an AC magnetic field. The reason for the reference to “at least eddy-current losses” is that hysteresis losses are conceivable. When solder material has magnetism, the solder material generates heat due to eddy-current losses and hysteresis losses.

For example, if a magnetic field has been generated in a lamination direction of the solder 10, an eddy current, which is a cause of eddy-current losses, increases in intensity with decreasing distance from surfaces of the first solder layer 11 and second solder layer 12. Consequently, the heat caused by eddy-current losses moves inward from the surface of the first solder layer 11 and moves inward from the surface of the second solder layer 12. Besides, because the first solder layer 11 and the second solder layer 12 are placed in thermal contact with each other, the heat generated by the eddy-current losses moves through opposing surfaces of the first solder layer 11 and second solder layer 12. Thus, the solder 10 can be raised in temperature in a shorter time than preform solder having a single-layer structure.

Examples of solder material include binary alloys and ternary and further multi-element alloys. Examples of the binary alloys include Sn—Sb alloys, Sn—Pb alloys, Sn—Cu alloys, Sn—Ag alloys, Sn—Bi alloys, and Sn—In alloys. Examples of the multi-element alloys include alloys produced by adding one or more metals selected from the group consisting of Sb, Bi, In, Cu, Zn, As, Ag, Cd, Fe, Ni, Co, Au, Ge, and P to any of the binary alloys described above.

The solder material of the first solder layer 11 may have either a same composition as, or a different composition from, the material of the second solder layer 12. The former case enables soldering by taking advantage of high mutual affinity of the two. The latter case enables soldering by taking advantage of a difference in composition or melting point (which refers to solidus temperature or liquidus temperature; the same applies hereinafter) between solder materials. However, in the latter case, preferably the difference in melting point is equal to or lower than a predetermined value. The predetermined value is set appropriately according to the composition of the solder material or the objects to be bonded together to such a temperature that will not obstruct an original bonding function of the solder material. The difference in melting point may be set larger than the predetermined value if two-stage bonding at different temperatures is intended.

When the solder according to the present embodiment is to have a laminated structure made up of three or more layers, another layer is added between the first solder layer 11 and the second solder layer 12 or to an outermost surface of the solder. The solder material of the other layer may be either the same as, or different from, the material of the first solder layer 11 or second solder layer 12. When solder materials constituting at least two layers differ from each other, the predetermined value is set as a preferable difference between the highest melting point and the lowest melting point.

The first solder layer 11 and the second solder layer 12 are bonded together by a publicly known technique. Examples of publicly known techniques include a roll cladding process.

The solder according to the present embodiment may contain a magnetic substance. FIGS. 2 and 3 are schematic diagrams showing examples in which the solder according to the present embodiment contains a magnetic substance. Solder 20 shown in FIG. 2 and solder 30 shown in FIG. 3 include the first solder layer 11 and the second solder layer 12. That is, the solder 20 and solder 30 have the same laminated structure as the solder 10 shown in FIG. 1.

However, the solder 20 contains a magnetic substance 21 in the first solder layer 11 and the second solder layer 12. The solder 30 includes a magnetic layer 31 between the first solder layer 11 and the second solder layer 12. Note that the magnetic substance 21 shown in FIG. 2 may be contained in only one of the first solder layer 11 and the second solder layer 12. The magnetic layer 31 shown in FIG. 3 may be provided on an outermost surface of the solder 30. The magnetic layer 31 may be provided both between the first solder layer 11 and the second solder layer 12 and on the outermost surface of the solder 30. That is, the total number of magnetic layers 31 may be two or more.

The magnetic substance 21 and the magnetic layer 31 are made of magnetic material. The magnetic material has the property of generating heat due to at least hysteresis losses when placed in an AC magnetic field. The reason for the reference to “at least hysteresis losses” is that eddy-current losses are conceivable. When the magnetic material is a conductor, the magnetic material generates heat due to hysteresis losses and eddy-current losses. When placed in an AC magnetic field, the magnetic material generates heat and rises in temperature more quickly than the solder material. Therefore, when the solder material is placed in the same AC magnetic field as the magnetic material, the solder material is heated by the surrounding magnetic material. That is, when the solder material and the magnetic material are placed in the same AC magnetic field, the rate of temperature rise increases compared to when the solder material is placed singly in the AC magnetic field and the melting point is exceeded in a shorter time.

The magnetic material is not specifically limited. For example, one metal selected from among ferromagnetic metal, paramagnetic metal, and diamagnetic metal can be used as the magnetic material. Examples of the ferromagnetic metal include Ni, Co, Fe, Gd, and Tb. Examples of the paramagnetic metal include Y, Mo, and Sm. Examples of the diamagnetic metal include Cu, Zn, and Bi. Examples of the magnetic material include an alloy, an oxide, or a nitride containing at least one of the metals mentioned above. Examples of ferromagnetic metal oxides include Fe₃O₄, γ-Fe₂O₃, and ferrite composed principally of Fe₃O₄. Examples of paramagnetic metal oxides include Tb₃O₄ and Sm₂O₃. Examples of diamagnetic metal oxides include CoO, NiO, α-Fe₂O₃, and Cr₂O₃. Examples of ferromagnetic metal nitrides include Fe₃N.

The stronger the magnetism of the magnetic material, the larger the hysteresis losses. Increases in hysteresis losses result in an increased amount of generated heat, and thus in increases in the rate of temperature rise of the magnetic material. The increases in the rate of temperature rise facilitate heating of the surroundings by the magnetic material. Thus, from the viewpoint of facilitating heating by the magnetic material, preferably the magnetic material has ferromagnetism. Specifically, it is preferable to select at least one magnetic material from ferromagnetic metals, oxides and nitrides of the ferromagnetic metals, ferromagnetic alloys, and oxides and nitrides of the ferromagnetic alloys.

Preferably the proportion of the magnetic material is 0.005% to 20% by weight (wt%). The proportion is calculated with reference to the entire laminated structure. The reason why the upper limit is set to 20% by weight is that a value larger than 20% by weight will make it difficult for the solder in a molten state to cohere and will obstruct an original bonding function of the solder material. From the viewpoint of reducing the impact on the bonding function, preferably the upper limit is 5% by weight, more preferably 0.9% by weight, and still more preferably 0.5% by weight.

The magnetic layer 31 is formed by applying a mixture of magnetic material and a binder to the surface of the first solder layer 11 or second solder layer 12. The binder is not specifically limited as long as the binder keeps the magnetic layer 31 from separating from the first solder layer 11 and the second solder layer 12. Examples of the binder include a flux described later.

The solder according to the present embodiment may contain a flux. When contained in the solder according to the present embodiment, the flux may be contained inside the solder. Specifically, as with the magnetic substance 21 shown in FIG. 2, the flux may be contained inside the first solder layer 11 and the second solder layer 12. The flux may be provided on a surface of the solder. Specifically, as with the magnetic layer 31 shown in FIG. 3, the flux may be provided between the first solder layer 11 and the second solder layer 12. The flux may be provided on the outermost surface of the solder 30.

The flux is not specifically limited, and a typical flux may be used. The flux includes a resin (base resin), a solvent, and various additives. Examples of the resin include rosin-based resins, acrylic resins, polyester, polyethylene, polypropylene, polyamide, epoxy resins, and phenol resins. Examples of the solvent include alcohols such as ethanol, isopropyl alcohol, and butanol; hydrocarbons such as toluene and xylene; esters such as isopropyl acetate and butyl benzoate; and glycol ethers such as ethyleneglycol and hexyl diglycol. Examples of the various additives include activators, thixotropic agents, antioxidants, surface active agents, antifoaming agents, and corrosion inhibitors.

When the solder according to the present embodiment contains a flux, there is no particular limit to the proportion of the flux to the entire laminated structure. The proportion of the flux is, for example, 5% to 95% by weight.

### 2. Examples of Bonding Method Using Preform Solder

### 2.1 Bonding Using Induction Heating Device

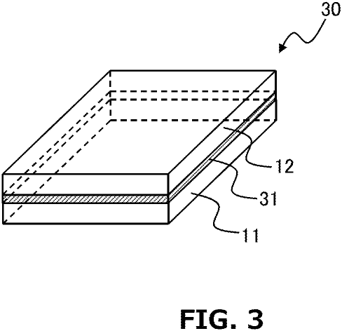

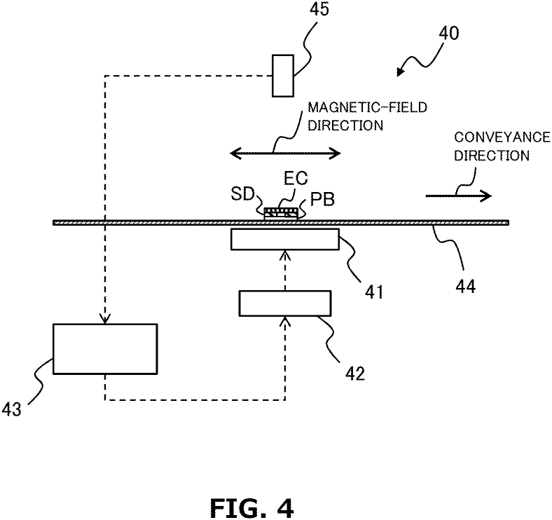

FIG. 4 is a diagram showing an example of a first bonding method using the solder according to the present embodiment. An induction heating device 40 shown in FIG. 4 includes a heating coil 41, an inverter circuit 42, a control circuit 43, a conveyer 44, and a temperature sensor 45. Note that the solder according to the present embodiment is placed between an electronic component EC and a printed board PB as “solder SD” for use to bond together an electrode of the electronic component EC and an electrode pattern printed on the printed board PB. Examples of the electronic component EC include an IC chip.

The heating coil 41 is provided behind the conveyer 44. The heating coil 41 heats an entire circuit board CB including the solder SD by induction heating. By being supplied with electric power from an AC power source (not shown), the inverter circuit 42 supplies high frequency current to the heating coil 41. The control circuit 43 is made up of a microcomputer. The control circuit 43 controls driving of the inverter circuit 42 based on various signals inputted to the control circuit 43. The various signals include a drive request signal and a signal that indicates the temperature around the circuit board CB. The conveyer 44 conveys the circuit board CB. The temperature sensor 45 detects the temperature around the circuit board CB. The temperature sensor 45 may generate temperature distribution information by image processing.

In the example shown in FIG. 4, as the conveyer 44 is driven, the circuit board CB is conveyed to the position of the heating coil 41. The conveyance of the circuit board CB is stopped at this position, and the inverter circuit 42 is driven based on the drive request signal. Consequently, an AC magnetic field is generated around the circuit board CB and the solder material of the solder SD generates heat due to at least eddy-current losses and melts. When an ending condition is satisfied, the driving of the inverter circuit 42 is stopped, or the circuit board CB is conveyed to outside the position of the heating coil 41 as the conveyer 44 resumes being driven. Subsequently, as the solder SD is cooled, the electrode of the electronic component EC and the electrode pattern are electrically connected to each other. Note that the ending condition is, for example, that a predetermined period of time elapses after the temperature around the circuit board CB reaches the melting point of the solder SD. Note that when the solder SD contains magnetic material, the solder material of the solder SD melts as a result of heat generation caused by eddy-current losses as well as heating by the magnetic material.

### 2.2 Bonding by Microwave Heating Device

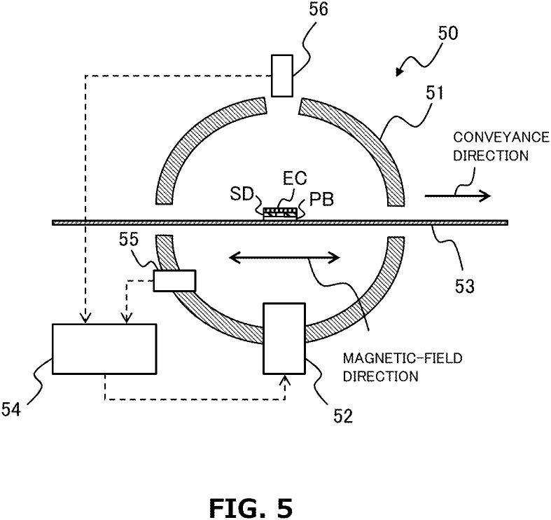

FIG. 5 is a diagram showing an example of a second bonding method using the solder according to the present embodiment. A microwave heating device 50 shown in FIG. 5 includes a cavity resonator 51, a microwave feeder 52, a conveyer 53, a controller 54, an electromagnetic wave sensor 55, and a temperature sensor 56. Note that as with the example shown in FIG. 4, the solder according to the present embodiment is placed between the electronic component EC and the printed board PB.

The cavity resonator 51 has a cylindrical interior space in which microwave irradiation is performed. The microwave feeder 52 generates a microwave as a specific standing wave in the interior space. Examples of the specific standing wave include a standing wave called TM110. The conveyer 53 conveys the circuit board CB by passing through the interior space. Based on various signals, the controller 54 adjusts the frequency of the microwave emitted from the microwave feeder 52. The various signals include a drive request signal, a signal indicating the resonance status of the standing wave generated in the interior space, and a signal indicating the temperature around the circuit board CB. The electromagnetic wave sensor 55 detects the resonance status of the standing wave. The temperature sensor 56 detects the temperature around the circuit board CB. The temperature sensor 56 may generate temperature distribution information by image processing.

In the example shown in FIG. 5, the controller 54 drives the microwave feeder 52 based on the drive request signal. The controller 54 calculates a target value (target frequency) of oscillation frequency of the microwave based on the signal indicating the resonance status of the standing wave and the controller 54 outputs the target value to the microwave feeder 52. When it is verified that a standing wave has been formed, the conveyer 53 is driven and the circuit board CB is conveyed to a specific position in the cavity resonator 51. Examples of the specific position include the position of a central axis of the interior space. The target frequency is calculated repeatedly by the controller 54 during the conveyance of the circuit board CB. As the target frequency is calculated repeatedly, a region extremely low in electric field intensity and high in magnetic field intensity is created at the specific position.

When the circuit board CB passes the specific position, an AC magnetic field being generated at this position acts on the circuit board CB. Consequently, the solder material of the solder SD generates heat due to at least eddy-current losses and melts. When the ending condition is satisfied, the driving of the microwave feeder 52 is stopped, or the circuit board CB is conveyed to outside the microwave feeder 52 as the driving of the conveyer 53 is resumed. Subsequently, as the solder SD is cooled, the electrode of the electronic component EC and the electrode pattern are electrically connected to each other. Based on the signal indicating the temperature around the circuit board CB, the controller 54 adjusts microwave output. For example, when the temperature around the circuit board CB reaches a predetermined temperature, the controller 54 reduces output. As another example, the closer the temperature around the circuit board CB is to the melting point of the solder SD, the more greatly the controller 54 reduces output. Note that when the solder SD contains magnetic material, the solder material of the solder SD melts as a result of heat generation caused by eddy-current losses as well as heating by the magnetic material.

### 3. Examples

Next, the present invention will be described in detail below with reference to Examples.

### 3.1 Example 1

Solder pieces of a predetermined size (10 mm long by 10 mm wide by 0.2 mm thick) were cut out from preform solder (produced by Senju Metal Industry Co., Ltd.; composition: Sn-3.0 Ag-0.5 Cu; melting point: 217° C. to 220° C.). Next, samples Ex. 1 to Ex.3 with a varied number of solder piece layers and comparison samples Re.1 to Re.2 were produced. Also, samples Ex.4 to Ex.5 and Re.3 to Re.4 were produced using two types of preform solder (both produced by Senju Metal Industry Co., Ltd.; composition Sn-5.0 Sb; melting point: 240° C. to 243° C. and composition Sn-10Sb; melting point: 245° C. to 266° C.). Data on these samples are shown in Table 1.

TABLE 1

| | SOLDER COMPOSITION | NUMBER OF SOLDER LAYER | THICKNESS PER LAYER (mm) | THICKNESS OF SOLDER LAVER(mm) |
|---|---|---|---|---|
| Ex.1 | Sn-3.0Ag-0.5Ou | 2 | 0.05 | 0.1 |
| Ex.2 | Sn-3.0Ag~0.5Ou | 3 | 0.05 | 0.15 |
| Ex.3 | Sn-3.0Ag-0.5Ou | 4 | 0.05 | 0.2 |
| Ex.4 | Sn-5 0Sb | 2 | 0.2 | 0.4 |
| Ex.5 | Sn-10Sb | 2 | 0.2 | 0.4 |
| Re.1 | Sn-3.0Ag-0.5Ou | 1 | 0.05 | 0.05 |
| Re.2 | Sn-3.0Ag-0.5Ou | 1 | 0.2 | 0.2 |
| Re.3 | Sn-5.0Sb | 1 | 0.2 | 0.2 |
| Re.4 | Sn-10Sb | 1 | 0.2 | 0.2 |

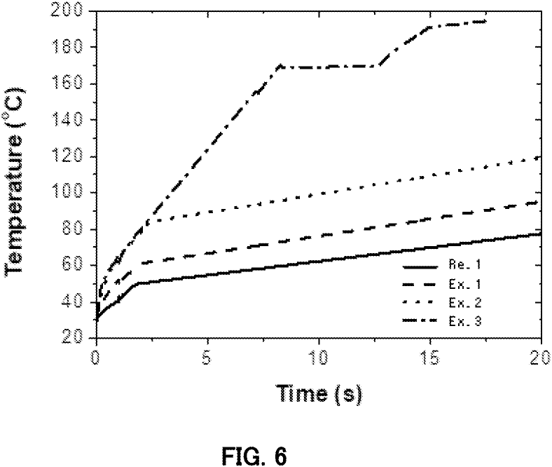

Next, a blackbody spray was applied to a surface of sample Ex. 1, and then sample Ex. 1 was installed at the position of the central axis of a cylindrical cavity resonator after being placed on a polyimide film. The cavity resonator is the cavity resonator 51 described in FIG. 5. Next, a standing wave was formed in the cavity resonator in TM110 mode and sample Ex. 1 was heated. The output power of the microwave was 50 W. During microwave irradiation, temperature T of sample Ex.1 was measured using a thermocamera. Temperatures T of other samples were measured using the same technique as the one used for sample Ex.1. Temperature rise history data of these samples are shown in FIG. 6.

As shown in FIG. 6, the rates of temperature rise of all samples Ex.1 to Ex.3 were higher than the rate of temperature rise of sample Re.1. It can be seen from this that the addition of magnetic material makes samples of solder material higher in the rate of temperature rise than the comparison sample. It can also be seen that the larger the number of solder layers, the higher the rate of temperature rise.

### 3.2 Example 2

A blackbody spray was applied to one surface of a solder piece described in relation to sample Ex.1, and Ni dispersed in ethanol was applied to the other surface to a uniform thickness using a spatula. After drying of the solder piece, another solder piece was laminated thereon to obtain sample Ex.6. Then, samples Ex.7 to Ex.8 were produced by forming an Ni layer between two solder pieces using the same technique as the one used for sample Ex.6. Data on these samples are shown in Table 2.

TABLE 2

| | SOLDER COMPOSITION | NUMBER OF SOLDER LAYERS | NUMBER OF MAGNETIC LAYERS | MAGNETIC SUBSTANCE | |
|---|---|---|---|---|---|
| | | | | COMPOSITION | CONTENT PERCENTAGE (wt%) |
| Ex.6 | Sn-3.0Ag-0.5Cu | 2 | 1 | Ni | 28.8 |
| Ex.7 | Sn-3.0Ag-0.5Cu | 3 | 2 | Ni | 35.1 |
| Ex.8 | Sn-3.0Ag-0.5Cu | 4 | 3 | Ni | 37.8 |

Next, using the same technique as the one used for sample Ex.1, samples Ex.6 to Ex.8 were heated by microwave. Temperature rise history data of these samples is shown in FIG. 6 together with temperature rise history data of sample Re.1.

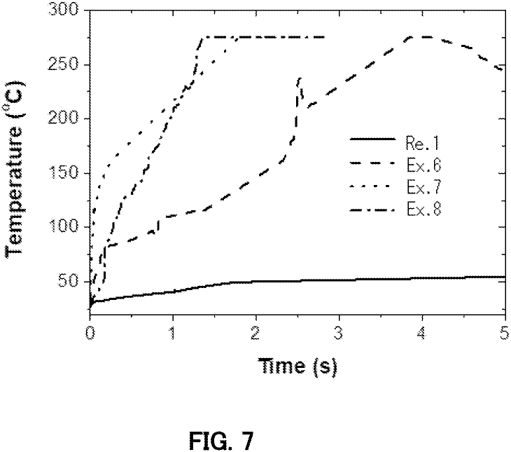

As shown in FIG. 7, the rates of temperature rise of all samples Ex.6 to Ex.8 were higher than the rate of temperature rise of sample Re.1. It can be seen from this that the samples produced by laminating an Ni layer on a solder layer have higher rates of temperature rise than does a sample made up of solder layers alone. When FIG. 6 and FIG. 7 are compared, it can be seen that the rate of temperature rise is higher when an Ni layer is placed among two or more solder layers than in the case of other samples.

### 3.3 Example 3

Sample paste was prepared by mixing solder paste (produced by Senju Metal Industry Co., Ltd.; composition: Sn-3.0Ag-0.5Cu; melting point: 217° C. to 220° C.) with powder of magnetic material in a mortar. Next, using a blade coating method, samples Ex.9 to Ex. 17 of a predetermined size (1 cm long by 1 cm wide by 60 µm thick) were produced on a polyimide film. The compositions of these samples are shown in Table 3.

Next, the polyimide film with sample Ex.9 formed thereon was placed at the position of the central axis of the cylindrical cavity resonator. The cavity resonator is the cavity resonator 51 described in FIG. 5. Next, a standing wave was formed in the cavity resonator in TM110 mode and sample Ex.9 was heated. The output power of the microwave was 50 W. During microwave irradiation, the temperature T of sample Ex.9 was measured using a thermocamera and the time required for the temperature T to reach a melting point TM of the solder material was measured. The rate of temperature rise was calculated by dividing the difference between the initial measurement value of the temperature T and the melting point TM by measured time requirement. The rates of temperature rise of samples Ex.10 to Ex.17 were calculated using the same technique as the one used for sample Ex. 9.

Comparison sample Re.5 with a size of 1 by 1 cm³ was produced using the solder paste alone. The rate of temperature rise of sample Re.5 was calculated using the same technique as the one used for samples Ex. 9 to Ex.17.

After the rates of temperature rise of the samples were calculated, the samples were evaluated with reference to the rate of temperature rise of sample Re.5. Any sample with a rate of temperature rise higher than that of sample Re. 5 was evaluated as “A” and any sample with a rate of temperature rise lower than that of sample Re.5 was evaluated as “F.” Evaluation results are shown in Table 3.

TABLE 3

| | MW OUTPUT | SOLDER MATERIAL (wt%) | MAGNETlC MATERIAL (wt%) | | | | | | | | | RATE OF TEMPERATURE RISE |
|---|---|---|---|---|---|---|---|---|---|---|---|---|
| | | Sn-3.0Ag-0.5Cu | Co | Y | Fe—Ni | Fe3O4 | Nd2O3 | Tb3O4 | Sm2O3 | Co3O4 | Fe3N | |
| Ex.9 | 50 W | 99.8 | 0.2 | - | - | - | - | - | - | - | - | A |
| Ex.10 | 50 W | 99.8 | - | 0.2 | - | - | - | - | - | - | - | A |
| Ex.11 | 50 W | 99.8 | - | - | 0.2 | - | - | - | - | - | - | A |
| Ex.12 | 50 W | 99.8 | - | - | - | 0.2 | - | - | - | - | - | A |
| Ex.13 | 50 W | 99.8 | - | - | - | - | 0.2 | - | - | - | - | A |
| Ex.14 | 50 W | 99.8 | - | - | - | - | - | 0.2 | - | - | - | A |
| Ex.15 | 50 W | 99.8 | - | - | - | - | - | - | 0.2 | - | - | A |
| Ex.16 | 50 W | 99.8 | - | - | - | - | - | - | - | 0.2 | - | A |
| Ex.17 | 50 W | 99.8 | - | - | - | - | - | - | - | - | 0.2 | A |
| Re.5 | 50 W | 100 | - | - | - | - | - | - | - | - | - | - |

As shown in Table 3, the rates of temperature rise of all samples Ex. 9 to Ex.17 were higher than that of sample Re.5. It can be seen from this that the addition of magnetic material makes samples of solder material higher in the rate of temperature rise than the comparison sample. It was found that the effect of increasing the rate of temperature rise is obtained regardless of the type of magnetic material. When attention was paid to the type of magnetic material, it was found that magnetic materials (Co, Fe₃O₄, Fe—Ni, and Fe₃N) having ferromagnetism tend to be higher in the rate of temperature rise than are magnetic materials (Y, Nd₂O₃, Tb₃O₄, Sm₂O₃, and Co₃O₄) having paramagnetism or diamagnetism.

### 3.4 Example 4

Using solder paste (produced by Senju Metal Industry Co., Ltd.; composition: Sn-58Bi; melting point: 139° C.), solder paste (produced by Senju Metal Industry Co., Ltd.; composition: Sn-10Sb; melting point: 245° C. to 266° C.), and magnetic material, samples Ex.18 to Ex.37 with varied proportions of the magnetic material were produced by the same technique as the one used for sample Ex. 9. Next, the samples were evaluated in terms of maximum temperature and cohesiveness. The maximum temperature is a maximum value of sample temperature for a period of five seconds from the start of microwave irradiation. Any sample whose maximum temperature was equal to or higher than the melting point of the solder material was evaluated as “A” and any other sample was evaluated as “F.” The cohesiveness was evaluated by visually checking the samples after melting. Any sample whose solder material was judged to have no problem in practical use in terms of cohesion was evaluated as “A.” Any sample judged to be at or above a certain level in terms of the cohesion of solder material was evaluated as “C” and any other sample was evaluated as “F.” Evaluation results are shown in Table 4.

TABLE 4

| | MW OUTPUT | SOLDER MATERIAL (wt%) | MAGNETIC MATERIAL (wt%) | | MAXIMUM TEMPERATURE | COHESIVENESS |
|---|---|---|---|---|---|---|
| | | Sn-58Bi | Ni | Fe3O4 | | |
| Ex.18 | 50 W | 99.995 | 0.005 | - | F | A |
| Ex.19 | 50 W | 99.99 | 0.01 | - | F | A |
| Ex.20 | 50 W | 99.95 | 0.05 | - | F | A |
| Ex.21 | 50 W | 99.9 | 0.1 | - | A | A |
| Ex.22 | 50 W | 99.5 | 0.5 | - | A | A |
| Ex.23 | 50 W | 99.1 | 0.9 | - | A | A |
| Ex.24 | 50 W | 99 | 1 | - | A | A |
| Ex.25 | 50 W | 95 | 5 | - | A | A |
| Ex.26 | 50 W | 90 | 10 | - | A | C |
| Ex.27 | 50 W | 80 | 20 | - | A | C |
| Ex.28 | 50 W | 99.995 | - | 0.005 | F | A |
| Ex.29 | 50 W | 99.99 | - | 0.01 | F | A |
| Ex.30 | 50 W | 99.95 | - | 0.05 | F | A |
| Ex.31 | 50 W | 99.9 | - | 0.1 | A | A |
| Ex.32 | 50 W | 99.5 | - | 0.5 | A | A |
| Ex.33 | 50 W | 99.1 | - | 0.9 | A | A |
| Ex.34 | 50 W | 99 | - | 1 | A | A |
| Ex.35 | 50 W | 95 | - | 5 | A | A |
| Ex.36 | 50 W | 90 | - | 10 | A | C |
| Ex.37 | 50 W | 80 | - | 20 | A | C |

As shown in Table 4, the maximum temperatures of samples Ex.21 to Ex.27 and Ex.31 to Ex.37 reached the melting point within five seconds from the start of microwave irradiation. On the other hand, the maximum temperatures of samples Ex.18 to Ex.20 and Ex.28 to Ex.30 did not reach the melting point within five seconds from the start of microwave irradiation. It can be seen from this that when the proportion of the magnetic material is small, the solder material is difficult to melt in a short time. Thus, the maximum temperature was evaluated by changing the output conditions of the microwave, and it was found that by increasing output, the maximum temperature can be adjusted to a desired value. Therefore, it was also found that it is desirable to change the microwave output according to the type and proportion of magnetic material.

As shown in Table 4, samples Ex.18 to Ex.25 and Ex.28 to Ex.35 were judged to have no problem in practical use in terms of the cohesion of solder material. On the other hand, samples Ex.26, Ex.27, Ex.36, and Ex.37 were judged to be at or above a certain level in terms of the cohesion of solder material. Thus, it was found that when the proportion of the magnetic material is 5% or below, the effect of increasing the rate of temperature rise can be obtained while reducing the impact on the original bonding function of the solder.

### REFERENCE SIGNS LIST

10, 20, 30, SD Solder
11 First solder layer
12 Second solder layer
21 Magnetic substance
31 Magnetic layer
40 Induction heating device
41 Heating coil
42 Inverter circuit
43 Control circuit
44, 53 Conveyer
45, 56 Temperature sensor
50 Microwave heating device
51 Cavity resonator
52 Microwave feeder
54 Controller
55 Electromagnetic wave sensor
EC Electronic component
PB Printed board

1-8. (canceled)

9. A Magnetic-field melting preform solder that melts by action of an AC magnetic field, wherein:
the preform solder comprises a laminated structure made up of two or more layers;
at least two layers constituting the laminated structure is made up of solder material;
the at least two layers do not contain ferromagnetic material;
each of the at least two layers includes a surface facing with each other; and
the surfaces facing with each other are in contact with each other.

10. The magnetic-field melting preform solder according to claim 9, wherein the laminated structure is made up of three or more layers.

11. The magnetic-field melting preform solder according to claim 9, wherein solder materials forming respective layers of the laminated structure have a same composition.

12. The magnetic-field melting preform solder according to claim 9, wherein:
the laminated structure is made up of three or more layers; and
the at least one of the layers contains magnetic material.

13. The magnetic-field melting preform solder according to claim 12, wherein the at least one of the layers is a magnetic layer made up of ferromagnetic material.

14. The magnetic-field melting preform solder according to claim 12, wherein the ferromagnetic material is at least one selected from ferromagnetic metals, oxides and nitrides of the ferromagnetic metals, ferromagnetic alloys, and oxides and nitrides of the ferromagnetic alloys.

15. The magnetic-field melting preform solder according to claim 12, wherein a proportion of the ferromagnetic material to the entire laminated structure is 0.005 to 20% by weight.

16. A bonding method using a magnetic-field melting preform solder that melts by action of an AC magnetic field, wherein:
the preform solder comprises a laminated structure made up of two or more layers;
at least two layers constituting the laminated structure is made up of solder material;
the at least two layers do not contain ferromagnetic material;
each of the at least two layers includes a surface facing with each other; and
the surfaces facing with each other are in contact with each other, the method comprising:
providing the preform solder between an electrode on a substrate and an electrode of an electronic component; and
bonding together the electrode on the substrate and the electrode of the electronic component by generating an AC magnetic field around the substrate and thereby melting the preform solder.
